(19) United States
(12) Patent Application Publication
(10) Pub. No.: US 2019/0064256 A1
(43) Pub. Date: Feb. 28, 2019

(54) TEST CIRCUIT, ARRAY SUBSTRATE AND MANUFACTURING METHOD THEREOF, AND DISPLAY DEVICE

(71) Applicants: BOE TECHNOLOGY GROUP CO., LTD., Beijing (CN); Fuzhou Boe Optoelectronics Technology Co., Ltd., Fujian (CN)

(72) Inventors: Yong WANG, Beijing (CN); Hongyan GUO, Beijing (CN); Yoseop CHEONG, Beijing (KR); Yang YU, Beijing (CN); Guiping ZHONG, Beijing (CN); Huailiang WU, Beijing (CN); Zongtian XIE, Beijing (CN); Cundui TANG, Beijing (CN); Zengyang JIANG, Beijing (CN)

(21) Appl. No.: 15/983,116

(22) Filed: May 18, 2018

(30) Foreign Application Priority Data
Aug. 31, 2017 (CN) 201710770229.7

(51) Int. Cl. G01R 31/28; H01L 27/12; G02F 1/1362; G02F 1/1345; G09G 3/00

(52) U.S. Cl. CPC G01R 31/2843; H01L 27/124; H01L 27/1262; G02F 1/136286; G09G 2330/12; G09G 3/006; G01R 31/2844; G02F 2001/136295; G02F 2001/136254; G02F 1/13458

(57) ABSTRACT

A test circuit including: a plurality of first leads; a plurality of controllable switches each having a control terminal for receiving a control signal, a first terminal connected to a respective one of the plurality of first leads, and a second terminal for connection to a respective first signal line; and at least two short-circuit lines intersecting the first leads. Each of the short-circuit lines is connected to a respective subset of the plurality of first leads. Each of the plurality of first leads belongs to a corresponding one of the respective subsets, and the respective subsets are disjoint from each other.

### CROSS-REFERENCE TO RELATED APPLICATIONS

This application claims the benefit of Chinese Patent Application No. 201710770229.7 filed on Aug. 31, 2017, the entire disclosure of which is incorporated herein by reference.

### TECHNICAL FIELD

The present disclosure relates to the field of displays, and in particular, to a test circuit, an array substrate and a manufacturing method thereof, and a display device.

### BACKGROUND

A display panel is usually provided with a test circuit for a light-on test in order to test whether the display panel has a defect. In the light-on test, test signals are supplied to the display panel through the test circuit, and then it is observed through a defect detection device whether each of the pixels of the display panel emits light normally. The test circuit has to be destroyed after the light-on test so as not to affect the normal operation of the display panel. This may lead to undesired damage of the display panel.

### SUMMARY

According to an aspect of the disclosure, a test circuit is provided comprising: a plurality of first leads; a plurality of controllable switches each having a control terminal for receiving a control signal, a first terminal connected to a respective one of the plurality of first leads, and a second terminal for connection to a respective first signal line; and at least two short-circuit lines intersecting the first leads. Each of the short-circuit lines is connected to a respective subset of the plurality of first leads. Each of the plurality of first leads belongs to a corresponding one of the respective subsets. The respective subsets are disjoint from each other.

In some embodiments, the test circuit further comprises a plurality of pads each connected to an end of a corresponding one of the short-circuit lines.

In some embodiments, the test circuit further comprises a plurality of second leads each connecting a respective one of the plurality of pads to the end of the corresponding short-circuit line.

In some embodiments, each of the pads is selected from the group consisting of a circular pad and a square pad.

In some embodiments, the pads are circular pads each having a diameter of 200 um to 400 um.

In some embodiments, the pads are square pads each having a side length of 200 um to 400 um.

In some embodiments, first ones of the pads, located at the same ends of the short-circuit lines, are arranged side by side and are spaced apart from each other.

In some embodiments, the test circuit further comprises at least one dummy pad arranged side by side with the first pads and spaced apart from each other.

In some embodiments, the test circuit further comprises a control line connected to the control terminals of the plurality of controllable switches to transmit the control signal to the control terminals.

In some embodiments, the control line is provided with a pad at at least one of both ends of the control line.

In some embodiments, the test circuit further comprises: a plurality of third leads, different from the first leads, for connection to respective second signal lines different from the first signal lines; a plurality of connecting lines each connected to a respective one of the plurality of third leads; and a plurality of additional pads each connected to an end of a corresponding one of the connecting lines.

In some embodiments, the test circuit further comprises a plurality of fourth leads each connecting a respective one of the plurality of additional pads to the end of the corresponding connecting line.

In some embodiments, the plurality of first leads comprises N subsets, and adjacent N ones of the first leads respectively belong to the N subsets, N being an integer greater than 1.

In some embodiments, N is equal to 2, 3, or 6.

In some embodiments, the controllable switches are transistors.

According to another aspect of the present disclosure, an array substrate is provided comprising the test circuit as described above.

According to yet another aspect of the present disclosure, a display device is provided comprising the array substrate as described above.

According to still yet another aspect of the present disclosure, a method of manufacturing an array substrate is provided, comprising: providing a base substrate on which a plurality of first signal lines are formed; and forming, on the base substrate, a plurality of first leads, a plurality of controllable switches, and at least two short-circuit lines intersecting the first leads. Each of the controllable switches has a control terminal for receiving a control signal, a first terminal connected to a respective one of the plurality of first leads, and a second terminal for connection to a respective one of the plurality of first signal lines. Each of the short-circuit lines is connected to a respective subset of the plurality of first leads. Each of the plurality of first leads belongs to a corresponding one of the respective subsets, and the respective subsets are disjoint from each other.

These and other aspects of the present disclosure will be apparent from and elucidated with reference to the embodiment(s) described hereinafter.

### BRIEF DESCRIPTION OF THE DRAWINGS

Further details, features and advantages of the disclosure are disclosed in the following description of exemplary embodiments in connection with the accompanying drawings, in which:

FIG. 1 is a circuit diagram of a test circuit according to an embodiment of the present disclosure;

FIG. 2 is a circuit diagram of a test circuit according to another embodiment of the present disclosure;

FIG. 3 is a schematic cross-sectional view of a controllable switch in a test circuit according to an embodiment of the present disclosure;

FIG. 4 is a block diagram of a display device according to an embodiment of the present disclosure; and

FIG. 5 is a flowchart of a method of manufacturing an array substrate according to an embodiment of the present disclosure.

### DETAILED DESCRIPTION

Although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present disclosure.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. Terms such as “before” or “preceding” and “after” or “followed by” may be similarly used, for example, to indicate an order in which light passes through the elements. The device may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

It will be understood that when an element or layer is referred to as being “on”, “connected to”, “coupled to”, or “adjacent to” another element or layer, it can be directly on, connected, coupled, or adjacent to the other element or layer, or intervening elements or layers may be present. In contrast, when an element is referred to as being “directly on,” “directly connected to”, “directly coupled to”, or “immediately adjacent to” another element or layer, there are no intervening elements or layers present. In no event, however, should “on” or “directly on” be construed as requiring a layer to completely cover an underlying layer.

Embodiments of the disclosure are described herein with reference to schematic illustrations of idealized embodiments (and intermediate structures) of the disclosure. As such, variations from the shapes of the illustrations as a result, for example, of manufacturing techniques and/or tolerances, are to be expected. Thus, embodiments of the disclosure should not be construed as limited to the particular shapes of regions illustrated herein but are to include deviations in shapes that result, for example, from manufacturing. Accordingly, the regions illustrated in the figures are schematic in nature and their shapes are not intended to illustrate the actual shape of a region of a device and are not intended to limit the scope of the disclosure.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

To make the objectives, technical solutions, and advantages of the present disclosure more comprehensible, embodiments of the present disclosure will be further described in detail below with reference to the accompanying drawings.

The light-on test of a display panel includes a full contact test and a shorting bar test. In the full contact test, probes are connected to data line leads in a lead area of the array substrate of the display panel, and data signals are supplied to the data line leads through the probes. Then, it is observed whether each of the sub-pixels has a defect. In the shorting bar test, a plurality of data line leads are connected to each other by using a shorting bar, and a data signal is supplied to the shorting bar through a probe to achieve simultaneous detection of a plurality of sub-pixels. After the test is completed, the shorting bar connected between the data line leads needs to be cut by a cutting process so as not to affect the normal operation of the display panel. Cutting the shorting bar not only causes an increase in the production process of the display panel, but also results in potential damage to the display panel. Based on this recognition, a test circuit solution is proposed that can be used for the light-on test of the display panel without performing a cutting process. However, it will be understood that the test circuit embodiments described below are not limited to the purpose of light-on tests.

FIG. 1 is a circuit diagram of a test circuit 10 according to an embodiment of the present disclosure. Referring to FIG. 1, the test circuit 10 includes a plurality of first leads 11, a plurality of controllable switches 13, and at least two short-circuit lines 12.

The plurality of first leads 11 are shown in FIG. 1 as being parallel to each other, although the present disclosure is not limited thereto. The first leads 11 can be regarded as an extension of the first signal lines 14 for applying test signals to the first signal lines 14. In the scenario of the light-on test, the first signal lines 14 may be data lines formed in an array substrate (not shown in FIG. 1). Alternatively, the first signal lines 14 may also be gate lines formed in the array substrate.

The plurality of controllable switches 13 each have a control terminal for receiving a control signal, a first terminal connected to a respective one of the plurality of first leads 11, and a second terminal for connection to a respective one of the first signal lines 14. In response to respective control signals, the controllable switches 13 are selectively turned on by bringing the first terminal into conduction with the second terminal, or turned off by bringing the first terminal out of conduction with the second terminal. In the example shown in FIG. 1, a control line 15 is provided for transmitting the same control signal to the respective controllable switches 13. In this case, the controllable switches 13 are controlled based on the same timing. Other embodiments are also contemplated. For example, a plurality of the control lines 15 may be provided to supply respective control signals to respective ones of the controllable switches 13. In this case, the controllable switches 13 can be controlled based on different timings. In some embodiments, the controllable switches 13 may be transistors, such as thin film transistors. In other embodiments, the controllable switches 13 may take other forms.

The at least two short-circuit lines 12 are each connected to a respective subset of the plurality of first leads 11. As shown in FIG. 1, each of the plurality of first leads 11 belongs to a corresponding one of the respective subsets, and the respective subsets are disjoint from each other. Specifically, each of the first leads 11 is connected to only one of the short-circuit lines 12, and each short-circuit line 12 is connected to at least one of the first leads 11. In the example shown in FIG. 1, the short-circuit lines 12 are arranged to cross the plurality of first leads 11. More specifically, the short-circuit lines 12 may be perpendicular to the first leads 11, although the present disclosure is not limited thereto. In addition, depending on the arrangement of the controllable switches 13, the control line 15 may or may not be parallel to the short-circuit line 12.

Due to the presence of the controllable switches 13, in the scenario of the light-on test, the test circuit 10 can be electrically connected to or disconnected from the signal lines 14 by turning on or off the controllable switches 13. As a result, in the process after the light-on test, the test circuit 10 is disconnected from the signal lines 14 by turning off the controllable switches 13 without the need to cut the short-circuit lines 12. This eliminates the cutting process and therefore eliminates the defects caused by the cutting process.

Also shown in FIG. 1 is a plurality of pads 100, each of which is connected to an end of a corresponding one of the short-circuit lines 12. This can facilitate supplying the test signal by the probe to the short-circuit lines 12. In the example shown in FIG. 1, the pads 100 are not directly connected to the short-circuit lines 12, but are connected to the end of the short-circuit lines 12 via respective second leads 12a. By providing the second leads 12a, the pads 100 can be disposed in an appropriate position. The pitch between the short-circuit lines 12 is generally small in order to reduce the area of the lead area where the first leads 11 are arranged, and thus reduce the size of the bezel of the display. Therefore, if the pads 100 are directly provided at the end of the short-circuit lines 12, a short circuit between the pads 100 would be easily caused. Moreover, due to the small pitch between the short-circuit lines 12, the area of the pad 100 is limited. This is solved by providing the connection leads 12a. Of course, other embodiments are possible. For example, the pads 100 may also be directly provided at the end of the short-circuit lines 12. In FIG. 1, the second leads 12a are arranged perpendicular to the first leads 11. This provides a simple wiring design and facilitates alignment of the probe and the pads 100. Further, as shown in FIG. 1, the control line 15 is provided, at both ends of the control line 15, with respective pads 100, facilitating supplying of the control signal to the control line 15. In some embodiments, the control line 15 may be provided with the pad 100 only at one end. The control line 15 may be connected to the pad 100 either by wires or directly. In some embodiments, the pad 100 of the control line 15 may be arranged side by side with the pads 100 of the short-circuit lines 12, as shown in FIG. 1. In this way, the pads of both the short-circuit line 12 and the control line 15 can be loaded with drive signals by a single probe with a suitable number of contacts, eliminating the need for separate control of the control line 15 and reducing the complexity of the light-on test.

The pads 100 can be circular pads or square pads that are easy to manufacture. In other embodiments, the pads 100 may have other shapes. The pads 100 may have a diameter of 200 um to 400 um where they are circular pads, and may have a side length of 200 um to 400 um where they are square pads. The pads 100 having such a size can facilitate alignment of the probe and the pads 100, while reducing defects such as burns and scratches by increasing the contact area between the probe and the pads 100.

The pads 100 at the same end of the short-circuit lines 12 are arranged side by side and spaced apart from each other. As shown in FIG. 1, the two pads 100 located at the left or right end of the two short-circuit lines 12 are arranged side by side and spaced apart from each other. This facilitates accurate alignment of the probe and pads 100. In this example, the arrangement direction of the pads 100 at the same end of the short-circuit lines 12 is parallel to the length direction of the short-circuit lines 12. In other embodiments, the pads 100 may be arranged in other directions, for example, parallel to the length direction of the first leads 11.

Also shown in FIG. 1 are two dummy pads 200 that are arranged side by side with the pads 100 at the same end of the short-circuit lines 12 and are spaced apart from each other. The dummy pads 200 are provided so that the pattern of the pads 100 and 200 can be adapted to the configuration of the contacts of the probe, improving the compatibility of the test circuit 10. In the example shown in FIG. 1, where the dummy pads 200 are not provided, a probe with 2 contacts is needed to load the test signals, and where the two dummy pads 200 are provided, either a probe with 3 contacts or a probe with 4 contacts can be used. It will be understood that the number of the dummy pads 200 is exemplary in FIG. 1, and in other embodiments, the test circuit 10 may include fewer or more dummy pads 200.

It will be understood that the test circuit 10 can also be used for a full contact light-on test where all controllable switches 13 are turned off and test signals are directly supplied to the first signal lines 14 for the light-on test.

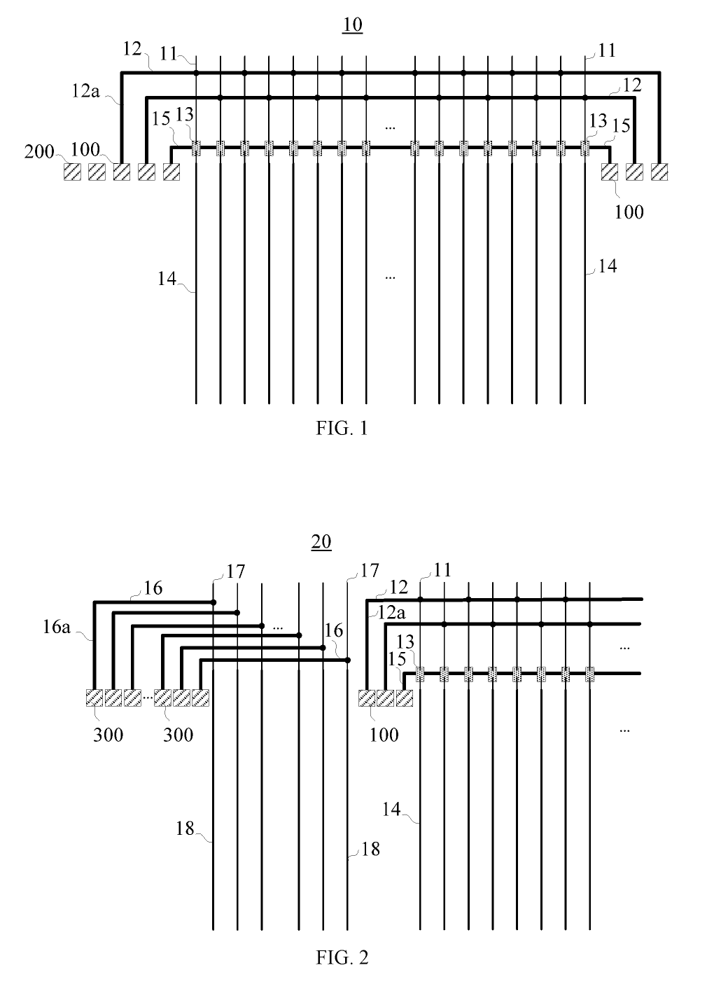

FIG. 2 is a circuit diagram of a test circuit 20 according to another embodiment of the present disclosure. Compared with the test circuit 10 shown in FIG. 1, the test circuit 20 further includes a plurality of third leads 17 for connection to respective second signal lines 18 different from the first signal lines 14, a plurality of connecting lines 16 respectively connected to the plurality of third leads 17, and a plurality of additional pads 300 respectively connected to the ends of the plurality of connecting lines 16.

The test circuit 20 may provide more test options than the test circuit 10. For example, in the scenario of the light-on test, the first signal lines 14 may be data lines in the array substrate, and the second signal lines 18 may be wires connected to gate driver on array (GOA) units. It is known that the GOA units are cascaded in the array substrate to provide gate signals to the gate lines in the array substrate. Therefore, during the light-on test, the test circuit 20 can also provide test options for the gate lines. For example, with the third lead 17, external input signals such as a clock signal CLK, a power supply voltage VDD, and a ground voltage VSS may be supplied to the GOA units. Furthermore, in addition to the light-on test, the pads 300 can also be used as electrical contacts between the array substrate and a flexible printed circuit (FPC) during bonding.

The pads 300 may be arranged in the same manner as the pads 100 described above. As shown in FIG. 2, the pads 300 are connected to the connecting lines 16 through respective fourth leads 16a, and are arranged side by side. Other aspects of the pads 300 may also be the same as the pads 100 and are omitted here.

It will be understood that in this embodiment, some of the third leads 17 may be located at one side (e.g., the left side, as shown in FIG. 2) of the first leads 11, and some of the third leads 17 may be located at the other side (e.g., the right side, not shown in FIG. 2) of the first leads 11. The two portions of the third leads 17 are separated by the first leads 11, and accordingly, the connecting lines 16 may also include two portions separated by the first leads 11. FIG. 2 shows only the connecting lines 16 and the third leads 17 at the left side of the first leads 11. In the example shown in FIG. 2, due to the space limitation between the third leads 17 and the first leads 11, the connecting lines 16 cannot be led out from both sides as the short-circuit lines 12, but are led out from only one side of the third leads 17. Specifically, for the third leads 17 at the left side of the first leads 11, their corresponding connecting lines 16 are also led out from the left side. For the third leads 17 at the right side of the first leads 11, their corresponding connecting lines 16 are also led out from the right side.

In the embodiments, the first leads 11 may include N subsets (N is an integer greater than 1), and adjacent N first leads 11 respectively belong to the N subsets. The value of N is the same as the number of the short-circuit lines 12. In this way, tests can be performed for the actual operating conditions of the display panel. For example, a polarity inversion test of a liquid crystal display panel may be achieved, or different data signals may be supplied to the red, green, and blue sub-pixels, respectively. In the examples shown in FIGS. 1 and 2, the first leads 11 include two subsets and any directly adjacent two of the first leads 11 belong to different subsets. This allows data signals of opposite polarity to be supplied to two directly adjacent columns of the sub-pixels to satisfy the test requirements of column inversion or dot inversion for the liquid crystal display panel. In other embodiments, the value of N may be 3 or 6, for example, to satisfy some specific test requirements. When N=3, separate tests for different color sub-pixels can be achieved. When N=6, separate tests for different color sub-pixels can be achieved while satisfying the test requirements for dot inversion or column inversion.

In the embodiments, each of the controllable switches 13 may be a transistor. In the scenario of the light-on test, the test circuits 10, 20 are typically fabricated on an array substrate. The use of the transistor as the controllable switch 13 is compatible with the fabrication of the array substrate. Further, the transistor may be a thin film transistor that has a gate connected to the control line 15, a first electrode connected to the first lead 11, and a second electrode connected to the signal line 14. When a certain voltage is applied to the gate of the thin film transistor through the control line 15, the thin film transistor is turned on, bringing the first lead 11 into conduction with the signal line 14. Depending on design choices, the thin film transistor may be of a bottom-gate type or a top-gate type.

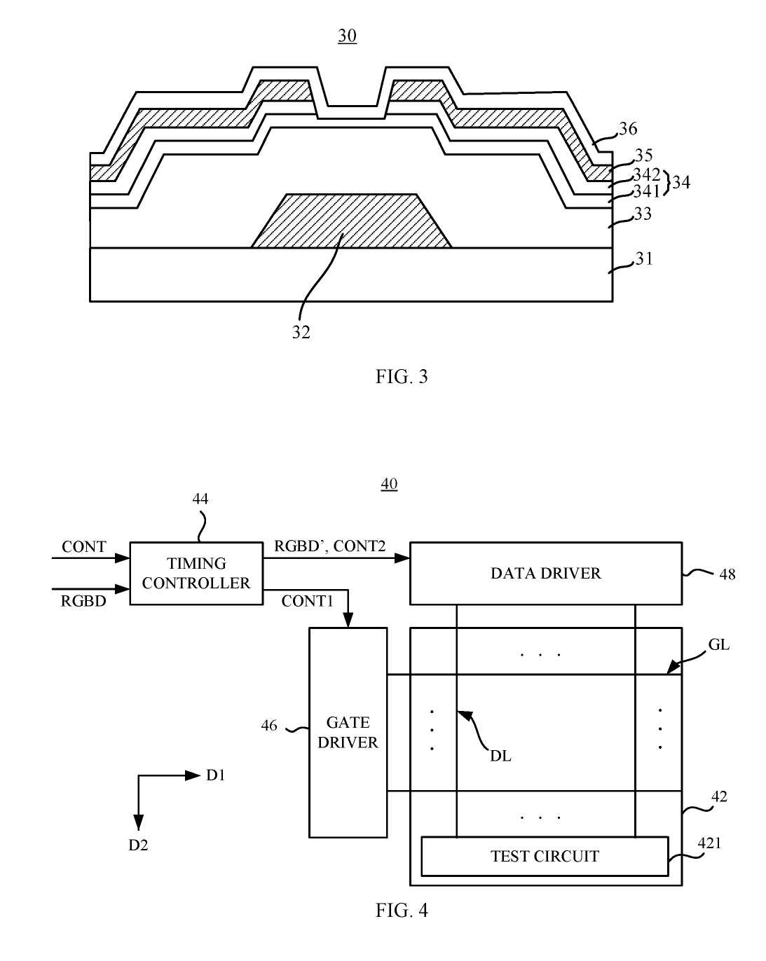

FIG. 3 is a schematic cross-sectional view showing a bottom-gate type thin film transistor 30 serving as the controllable switch 13 in the test circuits 10, 20. Referring to FIG. 3, the thin film transistor 30 includes a gate electrode 32, a gate insulating layer 33, an active layer 34, and source/drain electrodes 35, which are sequentially disposed on a base substrate 31. The thin film transistor 30 may further include a passivation layer 36 disposed on the source/drain electrodes 35, which may protect the thin film transistor 30 and may include silicon nitride or silicon oxynitride material.

The base substrate 31 may be a transparent base substrate, such as a glass base substrate, a silicon base substrate, a plastic base substrate, or the like. The gate insulating layer 33 may be a silicon nitride layer or a silicon oxynitride layer. The active layer 34 may be fabricated using amorphous silicon, microcrystalline silicon, or polysilicon. For example, the active layer 34 may include an amorphous silicon layer 341 disposed on the gate insulating layer 33 and an N-type doped amorphous silicon layer 342 disposed on the amorphous silicon layer 341. By arranging the N-type doped amorphous silicon layer 342 on the amorphous silicon layer 341, the amorphous silicon layer 341 can be prevented from direct contact with the source/drain electrodes 35, reducing lattice mismatch between the amorphous silicon layer 341 and the source/drain electrodes 35. The gate electrode 32 and the source/drain electrodes 35 may be metal electrodes, for example, made of metal such as Al, Cu, Mo, Ti, Cr, or the like. Transparent conductive materials such as ITO or IZO can also be used.

In the embodiments, the thin film transistor 30 may have the same type as the pixel thin film transistors in the array substrate. For example, when the pixel thin film transistors in the array substrate are bottom-gate thin film transistors, the thin film transistor 30 is also a bottom-gate thin film transistor. In this way, the thin film transistor 30 can be fabricated at the same time when the array substrate is manufactured, thereby saving the manufacturing process. Hereinafter, reference numerals 31, 32, and 35 are also used to indicate the base substrate, the gate layer, and the source/drain layers of the array substrate, respectively. The test circuits 10, 20 shown in FIGS. 1 and 2 are further described in conjunction with FIG. 3. Since each of the short-circuit lines 12 is selectively connected to at least two of the first leads 11, in some embodiments, the short-circuit lines 12 and the first leads 11 may be disposed in different layers, and each of the short-circuit lines 12 is connected to a respective subset of the first leads 11 through interlayer vias. The first leads 11 and the first signal lines 14 can be disposed in the same layer to facilitate the design and manufacture of the circuit. For example, when the first signal lines 14 are data lines (disposed on the source/drain layer 35 of the array substrate), the short-circuit lines 12 may be disposed on the gate layer 32 of the array substrate; when the first signal lines 14 are gate lines (disposed on the gate layer 32) of the array substrate, the short-circuit lines 12 may be disposed on the source/drain layer 35 of the array substrate. In this way, the arrangement of the first leads 11 and the short-circuit lines 12 in different layers can be achieved, and the fabrication of the short-circuit lines 12 can be made compatible with the fabrication of the gate layer pattern or the source/drain layer pattern. Since the short-circuit lines 12 are provided in the gate layer 32 or the source/drain layer 35 of the array substrate, the short-circuit lines 12 may be made of the same material as the gate layer 32 or the source/drain layer 35, such as, for example, metals such as Al, Cu, Mo, Ti, Cr, or transparent conductive materials such as Indium Tin Oxide (ITO) or Indium Zinc Oxide (IZO). In addition, the control line 15 may also be disposed on the gate layer 32 of the array substrate, and thus made of the same material as the gate layer 32, such as metals such as Al, Cu, Mo, Ti, Cr, or transparent conductive materials such as Indium Tin Oxide (ITO) or Indium Zinc Oxide (IZO). The third leads 17 and the connecting lines 16 may be disposed in different layers and connected via interlayer vias. For example, the third leads 17 are disposed at the gate layer 32, and the connecting lines 16 are disposed at the source/drain layer 35.

In other embodiments, the thin film transistor 30 may also have a different type from that of the pixel thin film transistors in the array substrate. For example, when the pixel thin film transistors in the array substrate are a bottom-gate type thin film transistor, the thin film transistor 30 may be a top-gate type thin film transistor. This provides design flexibility at the expense of process compatibility.

FIG. 4 is a block diagram of a display device 40 according to an embodiment of the present disclosure. Referring to FIG. 4, the display device 40 includes an array substrate 42, a timing controller 44, a gate driver 46, and a data driver 48. The display device 40 may be any product or component having a display function, such as a mobile phone, a tablet computer, a television, a monitor, a notebook computer, a digital photo frame, a navigator, and the like.

The array substrate 42 includes a plurality of gate lines GL and a plurality of data lines DL. The gate lines GL may extend in a first direction D1, and the data lines DL may extend in a second direction D2 intersecting (e.g., substantially perpendicular to) the first direction Dl. The array substrate 42 includes a plurality of pixels (not shown) arranged in a matrix. Each of the pixels may be electrically connected to a corresponding one of the gate lines GL and a corresponding one of the data lines DL.

The array substrate 42 also includes a test circuit 421, which may take the form of the test circuit 10 or 20 described above. The test circuit 421 is provided in a peripheral area of the array substrate 42. Although not shown, the array substrate 42 may also include an insulating protective layer that covers all the controllable switches of the test circuit 421 for, e.g., avoiding short circuits at the switches during bonding.

The timing controller 44 controls the operations of the array substrate 42, the gate driver 46, and the data driver 48. The timing controller 44 receives input image data RGBD and input control signals CONT from an external device (for example, a host). The input image data RGBD may include input pixel data for the plurality of pixels. Each input pixel data may include red gradation data R, green gradation data and blue gradation data B for a corresponding one of the plurality of pixels. The input control signals CONT may include a master clock signal, a data enable signal, a vertical synchronization signal, a horizontal synchronization signal, and the like. The timing controller 44 generates output image data RGBD', a first control signal CONT1, and a second control signal CONT2 based on the input image data RGBD and the input control signals CONT. In some embodiments, the output image data RGBD′ may be substantially the same image data as the input image data RGBD. In some embodiments, the output image data RGBD′ may be compensated image data generated by compensating the input image data RGBD. The first control signal CONT1 may include a vertical start signal, a gate clock signal, and the like. The second control signal CONT2 may include a horizontal start signal, a data clock signal, a data load signal, a polarity control signal, and the like.

The gate driver 46 receives the first control signal CONT1 from the timing controller 44. The gate driver 46 generates a plurality of gate signals for driving the gate lines GL based on the first control signal CONT1. The gate driver 46 sequentially applies the plurality of gate signals to the gate lines GL. In some exemplary embodiments, the gate driver 46 may be integrated in the array substrate 42 as a GOA circuit. Alternatively, the gate driver 46 may be connected to the array substrate 42 by, for example, a Tape Carrier Package (TCP).

The data driver 48 receives the second control signal CONT2 and the output image data RGBD′ from the timing controller 44. The data driver 48 generates a plurality of data voltages based on the second control signal CONT2 and the output image data RGBD′. The data driver 48 applies the plurality of data voltages to the data line DL. In some exemplary embodiments, data driver 48 may include a shift register, a latch, a digital-to-analog converter, and a buffer. The shift register can output a latch pulse to the latch. The latch may temporarily store the output image data RGBD′, and may output the output image data RGBD′ to the digital-to-analog converter. The digital-to-analog converter may generate analog data voltages based on the output image data RGBD′, and may output the analog data voltages to the buffer. The buffer can output the analog data voltages to the data lines DL.

The display device 40 and the array substrate 42 have the same advantages as the above-described test circuits 10, 20, which will not be repeated here.

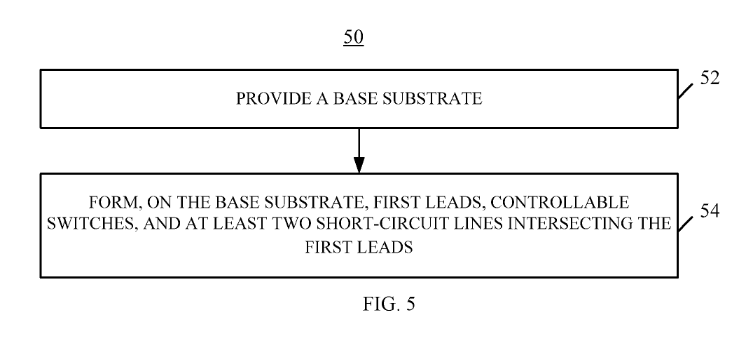

FIG. 5 is a flowchart of a method 50 of manufacturing an array substrate according to an embodiment of the present disclosure.

At step 52, a base substrate is provided. The base substrate may be a transparent base substrate such as a glass base substrate, a silicon base substrate, a plastic base substrate, or the like.

At step 54, a plurality of first leads, a plurality of controllable switches, and at least two short-circuit lines intersecting the first leads are formed on the base substrate. Each of the controllable switches has a control terminal for receiving a control signal, a first terminal connected to a respective one of the plurality of first leads, and a second terminal for connection to a respective one of the plurality of first signal lines. Each of the short-circuit lines is connected to a respective subset of the plurality of first leads. Each of the plurality of first leads belongs to a corresponding one of the respective subsets, and the respective subsets are disjoint from each other.

In some embodiments, the control line may be disposed at a gate layer of the array substrate for transmitting the same control signal to the respective controllable switches. In some embodiments, the controllable switch may be a transistor, such as a thin film transistor. The thin film transistor can be manufactured synchronously with the pixel thin film transistors in the array substrate. That is, the thin film transistor has the same structure as the pixel thin film transistors in the array substrate. The thin film transistor may be of a bottom-gate type or a top-gate type. Taking a bottom-gate type thin film transistor as an example, the fabrication of the thin film transistor may include sequentially fabricating a gate electrode, a gate insulating layer, an active layer, and source/drain electrodes on the base substrate.

In some embodiments, the first signal lines may be data lines in the array substrate. In such an embodiment, step 54 may be performed as follows. First, a gate layer pattern is formed on the base substrate, which gate layer pattern includes gate lines and the gate electrodes of the pixel thin film transistors located in a display area, as well as the short-circuit lines, the control line, and the gate electrodes and the pads (which may include pads for the short-circuit lines, pads for the connecting lines, dummy pads, etc.) of the controllable switches located in a lead area (i.e., a peripheral area of the display area). Then, a gate insulating layer and an active layer are sequentially formed. The gate insulating layer here includes both the gate insulating layer of the pixel thin film transistors and the gate insulating layer of the controllable switches. The active layer here includes both the active layer of the pixel thin film transistors and the active layer of the controllable switches. Then, vias connecting the short-circuit lines and the data line leads are formed on the gate insulating layer and the active layer, and a source/drain layer pattern are formed on the active layer. The source/drain layer pattern includes the source/drain electrodes of the pixel thin film transistors and the data lines located in the display area, and the first leads and the source/drain electrodes of the controllable switches in the lead area. In the above manufacturing processes, the gate electrodes, the source/drain electrodes, the data lines, the first leads, and the control line can all be made by patterning subsequent to sputtering. Of course, they can also be made in other ways.

In exemplary embodiments, the method 50 may further include forming an insulating protective layer in the lead area, which insulating protective layer covers all the controllable switches of the test circuit for avoiding a short circuit at the switches due to, for example, pressing during bonding.

Other details of the array substrate can be obtained by referring to the foregoing description with respect to FIGS. 1-4 and will not be repeated here.

The foregoing is only specific embodiments of the present disclosure and is not intended to limit the disclosure. Any modifications, equivalent replacements, and improvements of the described embodiments can be made by those skilled in the art without departing from the scope of the present disclosure. Therefore, these modifications, equivalent replacements, and improvements are all encompassed in the scope of the present disclosure.

What is claimed is:

1. A test circuit comprising:
a plurality of first leads;
a plurality of controllable switches each comprising:
a control terminal for receiving a control signal,
a first terminal connected to a respective one of the plurality of first leads, and
a second terminal for connection to a respective first signal line; and
at least two short-circuit lines intersecting the first leads, wherein each of the short-circuit lines are connected to a respective subset of the plurality of first leads, and
wherein each of the plurality of first leads belongs to a corresponding one of the respective subsets, and wherein the respective subsets are disjoint from each other.

2. The test circuit of claim 1, further comprising a plurality of pads each connected to an end of one of the short-circuit lines.

3. The test circuit of claim 2, further comprising a plurality of second leads each connecting a respective one of the plurality of pads to the end of the corresponding short-circuit line.

4. The test circuit of claim 2, wherein each of the pads is selected from the group consisting of a circular pad and a square pad.

5. The test circuit of claim 4, wherein the pads are circular pads each having a diameter of 200 um to 400 um.

6. The test circuit of claim 4, wherein the pads are square pads each having a side length of 200 um to 400 um.

7. The test circuit of claim 2, wherein first ones of the pads, located at the same ends of separate short-circuit lines, are arranged side by side and are spaced apart from each other.

8. The test circuit of claim 7, further comprising at least one dummy pad arranged side by side with the first ones of the pads and spaced apart from each other.

9. The test circuit of claim 1, further comprising a control line connected to the control terminals of the plurality of controllable switches to transmit the control signal to the control terminals.

10. The test circuit of claim 9, wherein the control line is provided with a pad at at least one of both ends of the control line.

11. The test circuit of claim 1, further comprising:
a plurality of third leads, different from the first leads;
a plurality of second signal lines, different from the first signal lines, wherein the plurality second signal lines each connect to respective third leads;
a plurality of connecting lines each connected to a respective one of the plurality of third leads; and
a plurality of additional pads each connected to an end of one of the connecting lines.

12. The test circuit of claim 11, further comprising a plurality of fourth leads each connecting a respective one of the plurality of additional pads to the end of the corresponding connecting line.

13. The test circuit of claim 1, wherein the plurality of first leads comprises N respective subsets, and wherein adjacent N ones of the first leads respectively belong to the N respective subsets, N being an integer greater than 1.

14. The test circuit of claim 13, wherein N is selected from the group consisting of 2, 3, and 6.

15. A test circuit according to claim 1, wherein the controllable switches are transistors.

16. An array substrate comprising the test circuit according to claim 1.

17. A display device comprising the array substrate of claim 16.

18. A method of manufacturing an array substrate, comprising:
providing a base substrate on which a plurality of first signal lines are formed; and
forming, on the base substrate:
a plurality of first leads,
a plurality of controllable switches, and
at least two short-circuit lines intersecting the first leads;
wherein each of the controllable switches has a control terminal for receiving a control signal, a first terminal connected to a respective one of the plurality of first leads, and a second terminal for connection to a respective one of the plurality of first signal lines,
wherein each of the short-circuit lines is connected to a respective subset of the plurality of first leads,
wherein each of the plurality of first leads belongs to a corresponding one of the respective subsets, and
wherein the respective subsets are disjoint from each other.
